(19) United States
(12) Patent Application Publication
(10) Pub. No.: US 2006/0246378 A1
(43) Pub. Date: Nov. 2, 2006

(54) Photolithographic process, stamper, use of said stamper and optical data storage medium

(76) Inventors: Jacobus Hermanus Maria Neijzen, Eindhoven (NL); Helmar Van Santen, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/553,720

(22) PCT Filed: Apr. 22, 2004
(86) PCT No.: PCT/IB04/50480

§ 371 Date: Oct. 18, 2005

(30) Foreign Application Priority Data
Apr. 23, 2003 (EP) 03101104.2

(51) Int. Cl. G03F 7/26

(52) U.S. Cl. 430/311; 430/322

(57) ABSTRACT

A photolithographic process is described. It comprises the steps of: applying a photoresist layer (2) on a substrate (1), locally exposing the photoresist layer (2) to a radiation source with a suitable wavelength, providing a suitable liquid developer composition on the substrate (1), dissolving an exposed or unexposed region of the photoresist layer (2) with the developer composition, rinsing and drying the photoresist layer (2) thereby interrupting said dissolving step. The substrate (1) has a metallic surface (1c) in contact with the photoresist layer (2) and the photoresist layer (2) has a thickness dr<100 nm. A relatively high photoresist wall steepness is achieved of 70 degrees or more. The process may be used for the production of high density optical data storage media by using a stamper (3) produced with said process.

The invention relates to a photolithographic process comprising the steps of:

applying a photoresist layer, with a substantially uniform thickness, on a substrate,

locally exposing the photoresist layer to a radiation source with a suitable wavelength,

providing a suitable liquid developer composition on the substrate,

dissolving an exposed or unexposed region of the photoresist layer with the developer composition,

rinsing and drying the photoresist layer thereby interrupting said dissolving step.

The invention further relates to a stamper produced using said process.

The invention further relates to the use of said stamper for the manufacture of optical data storage media

The invention further relates to an optical data storage medium manufactured using said stamper.

Conventional photoresist layers, e.g. positive novolac resin-based photoresists, are widely used in photolithographic processes. Spin-coating is the technique which is commonly used to apply the photoresist layer to the substrate. If very thin photoresist layers are required, less than 100 nm thick for instance, the photoresist lacquer is often diluted with a solvent to keep the rotational speeds during spin-coating within an acceptable range.

A disadvantage, which is encountered for thin photoresist layers is that the contrast and thereby the wall steepness of the structures to be made, appears to decrease with a decreasing photoresist layer thickness. Although the exact cause of this effect is unknown, chemical interaction of the photoresist layer with the substrate or with primer layers used to improve the adhesion between photoresist and substrate is the most likely explanation for the degradation of contrast. This trend is especially unfavourable since high resolution photolithography usually requires a reduction of photoresist layer thickness.

An example of this is found in deep-UV mastering of high density optical storage media, e.g. disks. The higher the density of the optical disk to be made, the thinner the photoresist layer will be. Thin photoresist layers, i.e. <100 nm, are demanded by the small depth of focus of the high resolution optical lithography technique as well as by the application itself. The stampers to be made require undeep structures with a high wall steepness.

For optical disk mastering of read-only (ROM) versions of the Blu-ray Disk (BD) generation (25 GB on a 12 cm disk) photoresist layers with a thickness of 80 nm or less are used. The standard substrate in this application is a glass disk coated with a thin photoresist layer. The wall steepness of the structures made in these thin novolac photoresist layers turns out to be less than 60 degrees in practice. As a consequence the highest spatial frequencies needed in the optical disks cannot be realized and replicated with sufficient amplitude and accuracy. In the read-out phase of the optical disks it leads to signals with insufficient amplitude in the highest frequencies and to unacceptable jitter values. So, a higher wall steepness is essential in this application to realize the mastering of high density optical discs with sufficient process margins.

A process of the type mentioned in the opening paragraph is known from U.S. Pat. No. 6,200,736.

U.S. Pat. No. 6,200,736 relates to a specific developer and (interrupted) development method used in an E-beam lithographic tool used to make transmissive reticles for the semiconductor industry. It is aimed at making steep structures in a relatively thick photoresist. This is achieved by a specific interrupted development method.

In this method a chromium (Cr) metal layer is present under the photoresist, which has to be structured in this reticle making process. The photoresist is a relatively thick photoresist of 400 nm, because it protects the underlying metal layer during e.g. dry etching. For optical disk mastering of ROM-disks the photoresist layer is applied “directly” to a substrate because no metal layer has to be structured. A very thin adhesion promoting layer may be present between the photoresist and the substrate. All what is used in this application is the photoresist topography after development, which is transferred to a stamper by replication techniques.

It is an object of the present invention to provide a process of the kind described in the opening paragraph, with improved photoresist wall steepness at a relatively thin photoresist thickness.

According to the invention this object is achieved with a process as described in the opening paragraph, which is further characterized in that the substrate has a metallic surface in contact with the photoresist layer and the photoresist layer has a thickness dr<100 nm.

Surprisingly applicants have found that by using a metallic surface under a relatively thin photoresist layer of smaller than 100 nm a high photoresist wall steepness is achieved. The whole substrate may be made of metal. A high photoresist wall steepness improves the contrast between photoresist and no-photoresist portions. It is assumed that a combination of thermal, optical and chemical influences causes the improved wall steepness effect.

In an embodiment the substrate comprises a metallic surface layer, with a thickness dm larger than approximately 10 nm, and a further substrate material. The wall steepness of the structures, e.g. pits, made in a 80 mm thick photoresist layer increases from values below 50 degrees to values above 65 degrees by adding this thin metal layer as an intermediate layer. It is preferred that the metallic surface comprises the chemical elements Ni, Cr or Au. These metals are relatively easy to deposit by e.g. sputtering or evaporation techniques. The photoresist layer thickness may be lower than 80 nm. The photoresist preferably is a novolac resin-based photoresist.

In a preferred embodiment the substrate is a master substrate for the production of a high density optical data storage medium. The positive effect of this invention is applicable for the case of mastering of high density optical data storage media using a novolac resin-based photoresist. For the new BD format UV mastering is used. The photoresist on the master substrate is locally exposed with a wavelength in the UV region by focusing a UV laser beam onto the substrate by means of a high quality and high numerical aperture (NA) diffraction limited UV transparent objective. In order to achieve a high NA the objective may be a liquid immersion objective.

From such a master substrate a stamper for the production of an optical data storage medium may be manufactured. This is normally done by making a negative metallic (Ni stamper) copy of the patterned surface of the master substrate in e.g. an electroplating process, which is known in the art. Especially the use of such a stamper for the manufacture of a high density optical data storage medium is advantageous because a high density optical data storage medium usually requires relatively shallow pits. The optimal pit depth is directly related to the wavelength of the radiation used to read out the medium. In case of high density optical data storage media this wavelength is e.g. 405 nm (BD format). For BD the pit depth is 80 nm or less. For future WV optical disk media even lower pit depths are required, e.g. 50 nm or less.

A high density optical data storage medium may be produced in an injection molding process by using the said stamper. Such an injection molding process is well known in the art.

The invention will be elucidated in greater detail with reference to the accompanying drawings, in which:

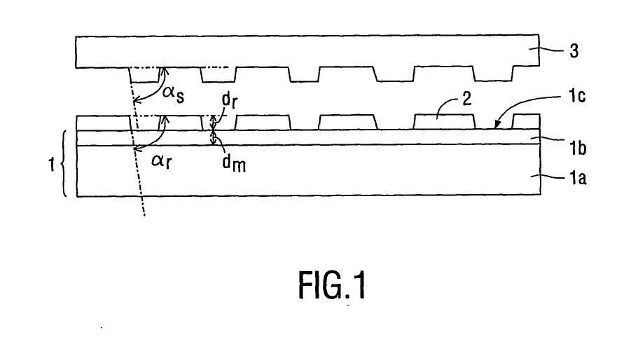

FIG. 1 schematically shows a cross section of a substrate including a positive photoresist layer used in the process according to the invention and the stamper, being a negative copy of the patterned surface of the substrate,

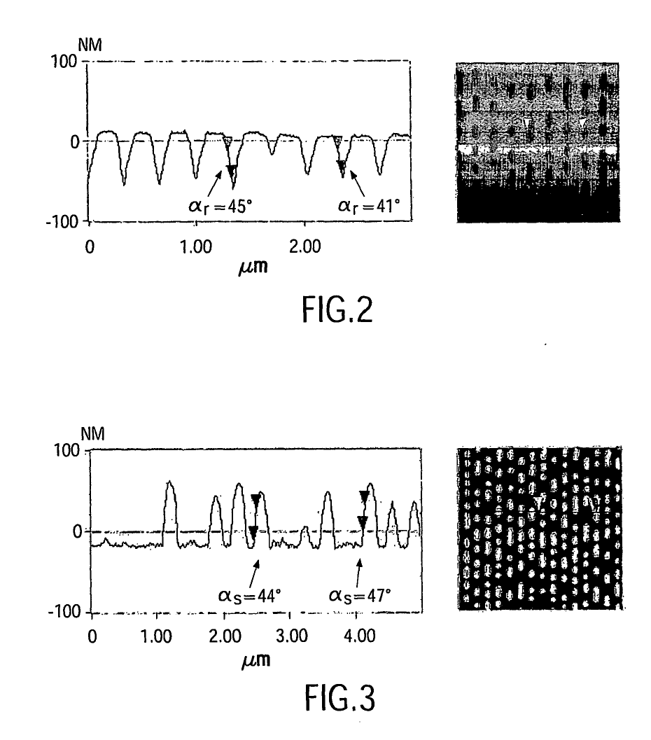

FIG. 2 shows a linear scan by an atomic force microscope (AFM) across the surface of a glass substrate including a developed positive photoresist, i.e. not according to the invention.

FIG. 3 shows a linear scan by an atomic force microscope (AFM) across the surface of a stamper made using the patterned surface of the substrate including the photoresist of FIG. 2.

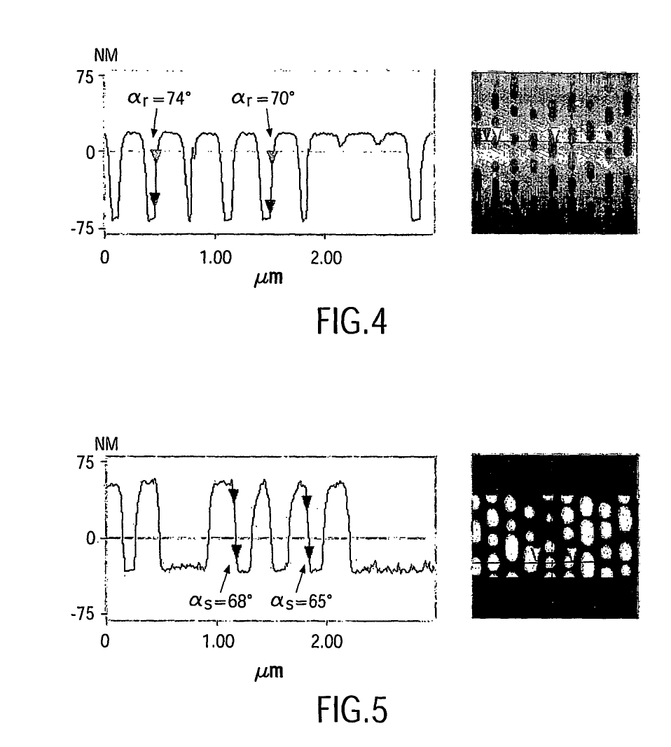

FIG. 4 shows a linear scan by an atomic force microscope (AFM) across the surface of a substrate including developed positive photoresist and a 10 nm Ni layer between the photoresist and the substrate, i.e. according to the invention.

FIG. 5 shows a linear scan by an atomic force microscope (AFM) across the surface of a stamper made using the patterned surface of a substrate including positive developed photoresist and a 10 nm Cr layer between the photoresist and the substrate, i.e. according to the invention.

In FIG. 1 a schematic cross section is shown of a substrate used in a photolithographic process. The process comprises the following steps. A positive novolac resin-based photoresist layer (Shipley Ultra i123) 2, with a substantially uniform thickness, is applied on a substrate 1. The photoresist layer 2 is locally exposed to a radiation source with a suitable wavelength. A suitable liquid developer composition is provided on the substrate 1, dissolving an exposed region of the photoresist layer 2. The photoresist layer is rinsed and dried thereby interrupting said dissolving step. The substrate 1 comprises a metallic surface layer 1b of Ni, with a thickness dm=10 nm, and a further substrate material 1a made of glass. The photoresist layer 2 has a thickness dr=80 nm.

The substrate 1 is a master substrate for the production of a high density optical medium. A stamper 3 may be manufactured by using the master substrate in an electroplating process, which is well known in the art. Other stamper making processes may include 2P replication and other resin based techniques known in the art. The stamper 3 surface is a negative copy of the patterned master substrate. The stamper 3 is used for the production of optical data storage media in an injection molding process.

FIGS. 2 and 3 respectively show a scan made with an atomic force microscope (AFM) of the photoresist surface after completion of the photolithographic process and of the resulting stamper 3 surface using the same 80 nm thick novolac photoresist without the presence of a metallic surface under the photoresist, i.e. not according to the invention. The wall steepness a of the pits is below 50 degrees in both cases, i.e. αᵣ=41-45 degrees for the photoresist and αₛ=44-47 degrees for the stamper. See FIG. 1 for the definition of αᵣ and αₛ.

FIG. 4 shows an AFM scan of the photoresist surface after completion of the photolithographic process when the same photoresist layer is applied on top of a substrate comprising a metallic surface layer 1b made of Ni with a thickness dm=10 nm, and a further substrate material made of glass.

FIG. 5 shows an AFM scan of the surface of a stamper. The stamper was made from the surface of a master substrate comprising a metallic surface layer 1b made of Cr with a thickness dm=10 nm under the same type developed photoresist. The further substrate material 1a is made of glass.

In both FIGS. 4 and 5 the wall steepness of the pits is close to or above 70 degrees in both cases, i.e. αᵣ=70-74 degrees for the photoresist and αₛ=65-68 degrees for the stamper. The measured wall steepness equals the steepness of the AFM tip. Hence, the real wall steepness may even be higher.

In the FIGS. 4 and 5 the positive effect of this invention has been demonstrated for the case of mastering of high density optical data storage media using a positive novolac resin-based photoresist. The higher wall steepness of the pits which is realized this way also results in significantly improved jitter values as well as improved signal amplitudes for the highest frequencies (the shortest pits).

The effects as described above have been observed for various metal layers. Sputtered Ni layers with a thickness between 10 and 100 nm and vacuum deposited Cr and Au layers with a thickness around 10 nm have been investigated. Similar improvement of wall steepness has been found in all cases.

Most experiments have been carried out with an i-line photoresist of Shipley: Ultra i123. For a second novolac photoresist that was tested, exactly the same behavior was found.

Thus, a promising field of application for the invention using a novolac resin-based photoresist is the optical mastering of high density optical disks, e.g. the Blu-ray Disk (BD) and Small Form Factor Optical disk (SFFO). This type of photoresist is also used in other photolithographic applications and the field of application is not limited to optical disk mastering but to any field where steep photoresist walls at relatively thin photoresist layer thicknesses are required.

However, in many applications the choice of layers below the photoresist is not free. That is a difference with the situation of optical disk mastering. In optical disk mastering the subsequent product, i.e. the stamper, is made by replication techniques. This gives almost complete freedom of choice for the substrate material or the intermediate layers under the photoresist.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising”, “comprise” or “comprises” does not exclude the presence of elements or steps other than those listed in a claim. The word “a” or “an” preceding an element does not exclude the presence of a plurality of such elements. The mere fact that certain measures are recited in mutually different dependent claims does not indicate that a combination of these measures cannot be used to advantage.

According to the invention a photolithographic process is described. It comprises the steps of: applying a photoresist layer on a substrate, locally exposing the photoresist layer to a radiation source with a suitable wavelength, providing a suitable liquid developer composition on the substrate, dissolving an exposed or unexposed region of the photoresist layer with the developer composition, rinsing and drying the photoresist layer thereby interrupting said dissolving step. The substrate has a metallic surface in contact with the photoresist layer and the photoresist layer has a thickness dr<100 nm. A relatively high photoresist wall steepness is achieved of 70 degrees or more. The process may be used for the production of high density optical data storage media by using a stamper produced with said process.

1. A photolithographic process comprising the steps of:
applying a photoresist layer (2), with a substantially uniform thickness, on a substrate (1),
locally exposing the photoresist layer (2) to a radiation source with a suitable wavelength,
providing a suitable liquid developer composition on the substrate (1),
dissolving an exposed or unexposed region of the photoresist layer (2) with the developer composition,
rinsing and drying the photoresist layer (2) thereby interrupting said dissolving step,
wherein the substrate (1) has a metallic surface (1c) in contact with the photoresist layer (2) and the photoresist layer (2) has a thickness dr<100 nm.

2. A photolithographic process a claimed in claim 1, wherein the substrate comprises a metallic surface layer (1b), with a thickness dm larger than approximately 10 nm, and a further substrate material (1a).

3. A photolithographic process a claimed in claim 1, wherein the metallic surface (1c) comprises the chemical elements Ni, Cr or Au.

4. A photolithographic process as claimed in claim 1, wherein the photoresist (2) is a positive novolac resin-based photoresist.

5. A photolithographic process a claimed in claim 1, wherein the substrate (1a, 1b) is a master substrate for the production of a high density optical medium.

6. A stamper (3) for the production of optical data storage media, manufactured by using the master substrate as used in claim 5.

7. Use of a stamper (3) as claimed in claim 6 for the manufacture of a high density optical data storage medium.

8. An optical data storage medium produced in an injection molding process by using the stamper (3) of claim 6.
